(19) United States
(12) Patent Application Publication
(10) Pub. No.: US 2025/0259962 A1
(43) Pub. Date: Aug. 14, 2025

(54) SEMICONDUCTOR DEVICE

(71) Applicant: FUJI ELECTRIC CO., LTD., Kawasaki-shi (JP)

(72) Inventor: Seiichi TAKAHASHI, Matsumoto-city (JP)

(73) Assignee: FUJI ELECTRIC CO., LTD., Kawasaki-shi (JP)

(21) Appl. No.: 19/193,546

(22) Filed: Apr. 29, 2025

Related U.S. Application Data
(63) Continuation of application No. PCT/JP2024/008105, filed on Mar. 4, 2024.

(30) Foreign Application Priority Data
May 16, 2023 (JP) 2023-080826

(51) Int. Cl. H01L 23/00; H01L 23/29; H01L 23/31

(52) U.S. Cl. CPC H01L 24/45; H01L 23/293; H01L 23/3107; H01L 24/48; H01L 2224/45565; H01L 2224/45691; H01L 2224/48227

(57) ABSTRACT

A semiconductor device includes: a semiconductor chip having a first main electrode on a top surface side and a second main electrode on a bottom surface side; a bonding wire connected to the first main electrode; an insulating layer covering an outer circumference of the bonding wire; and a sealing material sealing the semiconductor chip, the bonding wire, and the insulating layer, wherein a ratio of a Young's modulus of the insulating layer to a Young's modulus of the sealing material is 10 or greater.

### CROSS-REFERENCE TO RELATED APPLICATION

This application is a Continuation of PCT Application No. PCT/JP2024/008105, filed on Mar. 4, 2024, and claims the priority of Japanese Patent Application No. 2023-080826, filed on May 16, 2023, the content of which are incorporated herein by reference.

### TECHNICAL FIELD

The present disclosure relates to semiconductor devices (semiconductor modules).

### BACKGROUND ART

JP2007-012831A discloses that a connection part of a bonding wire on a chip is coated with resin. JP2021-150466A discloses that an aluminum wire bonded to a semiconductor element is covered with a primer layer and is further covered with a first sealing layer. JP2000-228482A discloses a configuration including a semiconductor element mounted via a bonding wire, and a circuit substrate, in which the semiconductor element and the bonding wire are covered with resin coating material, and the surface of the resin coating material is further covered with silicone gel.

JP2012-015222A discloses a power semiconductor device with a configuration in which a semiconductor element and an aluminum wire are sealed with epoxy resin, and is further sealed with silicone gel so as to cover the epoxy resin. JP2019-009171A discloses that a bonding wire connected to a semiconductor element is covered with resin. JP2022-007343A discloses that a bonding wire connected between a substrate and a case and the connected parts are covered with resin having higher hardness than gel.

JP2017-224778A discloses a semiconductor device including a wire connected to a semiconductor element, a resin sealing material sealing the semiconductor element, and a semi-conductive film covering at least a part of the wire and arranged between at least a part of the wire and the resin sealing material. JP2017-147327A discloses a semiconductor device including a bonding wire bonded to a semiconductor element, a resin layer covering the bonded part of the bonding wire on the surface of the semiconductor element, and a gel filling material sealing the semiconductor element, the bonding wire, and the resin layer.

JP2012-231034A discloses a bonding wire for a semiconductor element including a bonding wire and a copper-ion diffusion suppressing layer covering the surface of the bonding wire. JP2002-170842A discloses that a bonding wire is covered with bubbled polymer. JPH09-260414A disclose a covered wire including a core wire covered with covering resin. JPH08-316264A discloses a semiconductor device in which a metal terminal of a semiconductor chip and a lead are covered with a covering wire, and the covering wire and the connecting part of the covering wire is further covered with resin.

JPH02-304943A discloses a covered wire including a core wire covered with covering resin. JPH02-266541A and JPS63-318132A each disclose that a metal terminal of the semiconductor chip and a lead are connected via a covered wire in which a surface of a metallic wire is covered with an insulating covering film.

WO2019/31513A1 discloses a semiconductor device including a bonding wire connecting a substrate and a semiconductor element, a first sealing layer sealing a space at a lower part below an apex of the bonding wire, and a second sealing layer provided at an upper part of the first sealing layer via the bonding wire.

### SUMMARY OF THE INVENTION

### Technical Problem

If voids such as bubbles inside a sealing material or separation of the sealing material are caused around a bonding wire connected to a semiconductor chip or the like, an electric field intensity is increased at the parts provided with such voids, which would decrease insulating reliability.

### Solution to Problem

In view of the foregoing problems, the present disclosure provides a semiconductor device having a configuration capable of enhancing insulating reliability around bonding wires.

An aspect of the present disclosure inheres in a semiconductor device including: a semiconductor chip having a first main electrode on a top surface side and a second main electrode on a bottom surface side; a bonding wire connected to the first main electrode; an insulating layer covering an outer circumference of the bonding wire; and a sealing material sealing the semiconductor chip, the bonding wire, and the insulating layer, wherein a ratio of a Young's modulus of the insulating layer to a Young's modulus of the sealing material is 10 or greater.

### BRIEF DESCRIPTION OF THE DRAWINGS

FIG. 1 is a cross-sectional view illustrating an example of a semiconductor device according to an embodiment;

FIG. 2 is a perspective view illustrating another example of the semiconductor device according to the embodiment;

FIG. 3 is a schematic view illustrating a bonding wire, an insulating layer, and a sealing material according to the embodiment;

FIG. 4 is a graph showing a relation between a covering thickness of the bonding wire and an electric field intensity according to the embodiment; and

FIG. 5 is a graph showing a relation between a diameter of the bonding wire and the electric field intensity according to the embodiment.

### DETAILED DESCRIPTION

With reference to the drawings, an embodiment of the present disclosure will be described below.

In the drawings, the same or similar elements are indicated by the same or similar reference numerals. The drawings are schematic, and it should be noted that the relationship between thickness and planer dimensions, the thickness proportion of each layer, and the like are different from real ones. Moreover, in some drawings, portions are illustrated with different dimensional relationships and proportions. The embodiment described below merely illustrate schematically devices and methods for specifying and giving shapes to the technical idea of the present disclosure, and the span of the technical idea is not limited to materials, shapes, structures, and relative positions of elements described herein.

Additionally, definitions of directions such as “upper and lower” and “left and right” in the following description are simply definitions for convenience of description, and do not limit the technological concept of the present disclosure. For example, when observing an object rotated by 90 degrees, the “upper and lower” is converted to “left and right” to be read, and when observing an object rotated by 180 degrees, the “upper and lower” are read reversed, which should go without saying.

In the following description, a “first main electrode” of a semiconductor chip means an electrode through which a main current flows into or flows out of the semiconductor chip. The “first main electrode” is assigned to any one of a source electrode or a drain electrode when the semiconductor chip implements a field-effect transistor (FET) or a static induction transistor (SIT). The “first main electrode” is assigned to any one of an emitter electrode or a collector electrode when the semiconductor chip implements an insulated-gate bipolar transistor (IGBT). The “first main electrode” is assigned to any one of an anode electrode or a cathode electrode when the semiconductor chip implements a static induction (SI) thyristor or a gate turn-off (GTO) thyristor. A “second main electrode” of the semiconductor chip is assigned to any one of the source electrode or the drain electrode, which is not assigned as the first main electrode, when the semiconductor chip implements the FET or the SIT. The “second main electrode” is assigned to any one of the emitter electrode or the collector electrode, which is not assigned as the first main electrode, when the semiconductor chip implements the IGBT. The “second main electrode” is assigned to any one of the anode electrode or the cathode electrode, which is not assigned as the first main electrode, when the semiconductor chip implement the SI thyristor or the GTO thyristor. That is, when the “first main electrode” is the source electrode, the “second main electrode” means the drain electrode. When the “first main electrode” is the emitter electrode, the “second main electrode” means the collector electrode. When the “first main electrode” is the anode electrode, the “second main electrode” means the cathode electrode.

### EMBODIMENT

### <Configuration of Semiconductor Device>

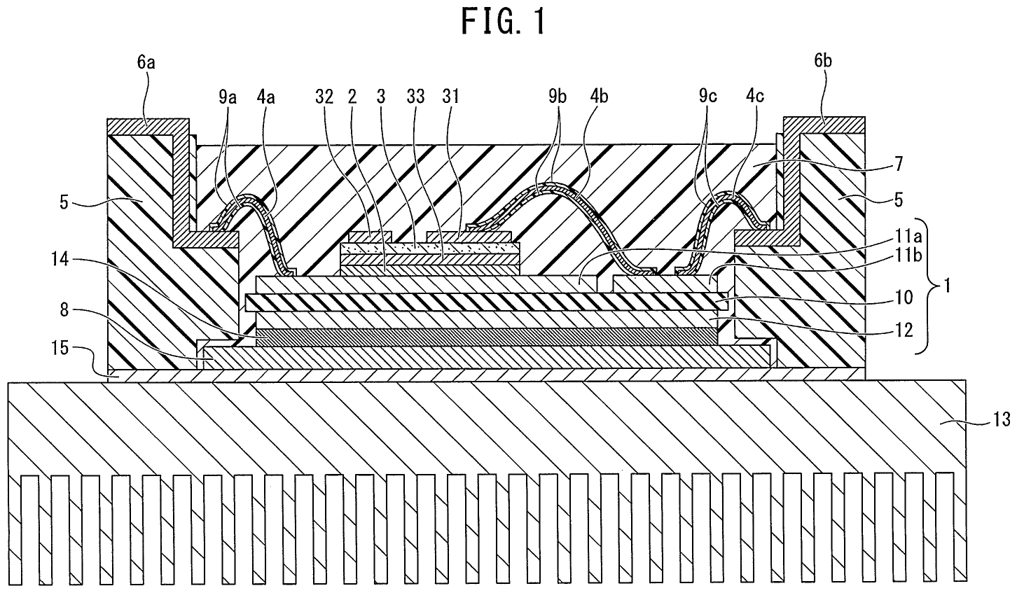

A semiconductor device (a semiconductor module) according to an embodiment includes an insulated circuit substrate 1, and a power semiconductor chip (a semiconductor chip) 3 provided on one of the main surface sides (on the top surface side) of the insulated circuit substrate 1 with a bonding layer 2 interposed, as illustrated in FIG. 1. A case 5 is arranged to surround the outer circumferences of the insulated circuit substrate 1, the bonding layer 2, and the semiconductor chip 3. Terminals (external connection terminals) 6a and 6b are attached to the case 5. The insulated circuit substrate 1, the semiconductor chip 3, and the external connection terminals 6a and 6b are electrically connected to each other via bonding wires 4a to 4c. A sealing material (sealing resin) 7 is provided inside the case 5 so as to seal the insulated circuit substrate 1, the bonding layer 2, the semiconductor chip 3, the bonding wires 4a to 4c, insulating layers 9a to 9c, and the like.

The insulated circuit substrate 1 is a direct copper bonded (DCB) substrate or an active metal brazed (AMB) substrate, for example. The insulated circuit substrate 1 includes an insulating plate 10, conductive layers 11a and 11b provided on one of the main surface sides (on the top surface side) of the insulating plate 10, and a conductive layer 12 provided on the other main surface side (on the bottom surface side) of the insulating plate 10. The insulating plate 10 is a ceramic substrate including material such as aluminum oxide (Al₂O₃), aluminum nitride (AlN), and silicon nitride (Si₃N₄), or a resin insulating substrate including polymer material or the like. The conductive layers 11a, 11b, and 12 are each a conductor foil using metal such as copper (Cu) and aluminum (Al), for example.

The bonding layer 2 includes solder or sintering material, for example. The solder to be used can be lead-free solder such as tin-antimony based (Sn—Sb), tin-copper based (Sn—Cu), tin-copper-silver based (Sn—Cu—Ag), tin-silver based (Sn—Ag), tin-silver-copper based (Sn—Ag—Cu), tin-silver-bismuth-copper based (Sn—Ag—Bi—Cu), tin-indium-silver-bismuth based (Sn—In—Ag—Bi), tin-zinc based (Sn—Zn), tin-zinc-bismuth based (Sn—Zn—Bi), tin-bismuth based (Sn—Bi), and tin-indium based (Sn—In) solder, or leaded solder such as tin-lead based (Sn—Pb) solder, for example. The sintering material to be used can be obtained such that a sintering sheet or conductive paste, including metallic grains of gold (Au), silver (Ag), copper (Cu) or the like having a fine grain diameter of about several nanometers to several micrometers and an organic component (a binder), is applied with pressure while being heated so as to be sintered.

The semiconductor chip 3 as used herein can be an insulated gate bipolar transistor (IGBT), a field-effect transistor (FET), a static induction (SI) thyristor, a gate turn-off (GTO) thyristor, or a freewheeling diode (FWD), for example. The semiconductor chip 3 is illustrated herein with a MOSFET. The semiconductor chip 3 may be implemented by a silicon (Si) substrate, or a semiconductor substrate using a wide bandgap semiconductor including silicon carbide (SiC), gallium nitride (GaN), gallium oxide (Ga₂O₃), or diamond (C), for example.

A maximum rated voltage of the semiconductor chip 3 is about 1.7 kV or higher, for example. The maximum rated voltage of the semiconductor chip 3 may be about 1.7 kV or lower, or may be about 3.3 kV or higher. An insulating distance necessary between the respective members increases as the maximum rated voltage of the semiconductor chip 3 is higher.

The semiconductor chip 3 is provided with a first main electrode (a source electrode) 31 and a gate electrode 32 on one of the main surface sides (on the top surface side), and is provided with a second main electrode (a drain electrode) 33 on the other main surface side (on the bottom surface side). The second main electrode 33 is bonded to the conductive layer 11a via the bonding layer 2. While FIG. 1 illustrates the single semiconductor chip 3, the present embodiment may include two or more semiconductor chips, and the number of the semiconductor chips may be determined as appropriate depending on a current capacity of the semiconductor module and the like.

The case 5 includes thermoplastic resin such as polyphenylene sulfide (PPS) and polybutylene terephthalate (PBT).

The external connection terminals 6a and 6b include metal material such as copper (Cu) and aluminum (Al). The external connection terminals 6a and 6b can be connected to an external circuit. The shape, the arranged positions, and the number of the external connection terminals 6a and 6b can be changed as appropriate. The external connection terminals 6a and 6b can be bonded to the conductive layers 11a and 11b via bonding layers including solder or sintering material without the use of the bonding wires 4a and 4b.

One end of the bonding wire 4a is connected to the conductive layer 11a, and the other end is connected to the external connection terminal 6a. The second main electrode 33 of the semiconductor chip 3 is electrically connected to the external connection terminal 6a via the conductive layer 11a and the bonding wire 4a.

One end of the bonding wire 4b is connected to the first main electrode 31 of the semiconductor chip 3, and the other end is connected to the conductive layer 11b. One end of the bonding wire 4c is connected to the conductive layer 11b, and the other end is connected to the external connection terminal 6b. The first main electrode 31 of the semiconductor chip 3 is electrically connected to the external connection terminal 6b via the bonding wire 4b, the conductive layer 11b, and the bonding wire 4c.

Although not illustrated in FIG. 1, the gate electrode 32 of the semiconductor chip 3 is electrically connected to another external connection terminal (not illustrated) connectable to the external circuit via a bonding wire (not illustrated).

A potential of the bonding wire 4a illustrated in FIG. 1 is equal to that of the external connection terminal 6a electrically connected to the second main electrode 33 of the semiconductor chip 3, and is different from that of the external connection terminal 6b electrically connected to the first main electrode 31 of the semiconductor chip 3. A potential of the respective bonding wires 4b and 4c is equal to that of the external connection terminal 6b, and is different from that of the external connection terminal 6a.

For example, the bonding wire 4a may be distant by about five millimeters or shorter from the external connection terminal 6b having a potential different from that of the external connection terminal 6b with the sealing material 7 interposed. The respective bonding wires 4b and 4c may be distant by about five millimeters or shorter from the external connection terminal 6a having a potential different from that of the respective bonding wires 4b and 4c with the sealing material 7 interposed.

The bonding wires 4a to 4c each include metal material such as copper (Cu), aluminum (Al), and gold (Au). The bonding wires 4a to 4c each have a diameter in a range of about 125 micrometers or greater and 500 micrometers or smaller, for example. The diameter of the respective bonding wires 4a to 4c may be about 400 micrometers or smaller, or may be about 300 micrometers or smaller. A size of a pad used for connecting the bonding wires 4a to 4c can be decreased and the element size can be decreased as the diameter of the bonding wires 4a to 4c is smaller. At the same time, an electric field intensity around the bonding wires 4a to 4c is increased as the diameter of the bonding wires 4a to 4c is smaller, and the insulating distance necessary between the bonding wires 4a to 4c and the other members is thus increased.

The sealing material 7 includes resin material such as gel-state silicone (silicone gel) and fluorine gel. The sealing material 7 has a modulus of longitudinal elasticity (a Young's modulus) in a range of about 1 kPa or greater and 100 kPa or smaller, for example. The sealing material 7 has relative permittivity set in a range of about three or greater and five or smaller, for example.

The sealing material 7 has a function so as to mechanically protect an internal circuit against foreign substances. If electrically-conductive foreign substances adhere to a part between exposed circuits, for example, the circuits are short-circuited and are thus damaged. Any foreign substances can cause a short circuit and damage because of tracking regardless of whether the substances have low electric conductivity. Covering the internal circuits with the sealing material 7 can avoid such a failure.

The sealing material 7 also has a function so as to insulate the respective electrodes (circuits) from each other. Covering the surfaces of the circuits, including the respective surfaces of elements, bonding wires, and terminals, and filling between the respective electrodes (circuits) with the sealing material 7 can ensure insulating reliability. The insulation between the respective electrodes by the sealing material 7 can decrease the insulating distance much more than air insulation, so as to achieve a reduction in size of the module with high-density packaging accordingly.

The gel such as silicone gel included in the sealing material 7 is soft and has high flexibility, and is thus hard to cause separation, but at the same time has high moisture absorbency (moisture permeability), which tends to internally cause bubbles. Increasing the hardness of the sealing material 7 can avoid bubbles, but also decreases the flexibility with respect to the bonding wires 4a to 4c and the like to thus lead the sealing material 7 to be easily separated. In addition, since a large number of fine gaps are provided in bonded parts between the sealing material 7 and the other members, the processing that can completely avoid voids is technically difficult. Filling voids with resin excessively increases stress upon thermal cycles and promotes damage risks during heat cycles and power cycles. Further, it is fundamentally difficult to completely fill voids with resin in a module having a large size.

The gel such as silicone gel included in the sealing material 7 has higher permittivity than air, and increases the electric field intensity in a part provided with voids such as bubbles or separation if caused in the sealing material 7 between the respective electrodes, leading to a decrease in insulating reliability. For example, a discharge-start voltage is decreased to about a third if voids are caused. Since the electric field tends to be concentrated particularly on the surfaces of the bonding wires 4a to 4c, the discharge-start voltage is decreased to as low as about a sixth with respect to the other regions. Further, the insulating performance is decreased as the bonding wires 4a to 4c are narrower.

When the maximum rated voltage of the semiconductor chip 3 is about 1.7 kV or lower, restrictions on design (size reduction) to be considered are not strict, since the insulating distance necessary for the bonding wires 4a to 4c is relatively small even if voids would be caused between the electrodes. However, the maximum rated voltage of the semiconductor chip 3 if increased to about 3.3 kV or higher impedes a reduction in size because the insulating distance necessary for the bonding wires 4a to 4c having a diameter of about 300 micrometers is inevitably longer than the insulating distance necessary for the bonding wires 4a to 4c having a diameter of about 125 micrometers in the case of having the maximum rated voltage of about 1.7 kV or lower.

The electric field intensity is increased when a distance between the respective bonding wires 4a to 4c and the other members having a different potential is about five millimeters or shorter, and the insulating performance is significantly decreased if bubbles are caused around the bonding wires 4a to 4c, which increases a risk of causing an electric discharge or a short-circuit failure. Increasing the distance between the respective bonding wires 4a to 4c and the other members having a different potential can reduce the risk of the short-circuit failure caused by bubbles, but also promotes an increase in voltage, a decrease in size, and high-density packaging, which impedes a sufficient insulating distance to be obtained. The increase in the diameter of the bonding wires so as to relax the electric field is an effective means, but inevitably leads to an increase in chip area and cost, and a problem of damage to pads used for connecting the bonding wires further needs to be considered.

In view of the problems described above, the semiconductor device according to the present embodiment has the structure in which the outer circumferences of the bonding wires 4a to 4c are covered with the insulating layers (covering layers) 9a to 9c. The insulating layers 9a to 9c include at least one kind of resin selected from the group consisting of polyamide resin, polyimide resin, polyamide imide resin, polyester resin, epoxy resin, phenol resin, fluorine resin, acrylic resin, silicone resin, polyolefin resin, and polyether imide resin, for example. The insulating layers 9a to 9c may include two or more kinds of the above resins.

The insulating layers 9a to 9c may be formed such that the bonding wires 4a to 4c are first bonded to the first main electrode 31 of the semiconductor chip 3, the conductive layers 11a and 11b, the external connection terminals 6a and 6b, and the like, and the outer circumferences of the bonding wires 4a to 4c are then covered with the insulating layers 9a to 9c applied by a method such as spraying, impregnation (dipping), and dispensing, for example. Alternatively, the bonding wires 4a to 4c such as enameled wires preliminarily covered with the insulating layers 9a to 9c may be prepared first, and the bonding wires 4a to 4c thus obtained may be then bonded to the first main electrode 31 of the semiconductor chip 3, the conductive layers 11a and 11b, the external connection terminals 6a and 6b, and the like.

While FIG. 1 illustrates the case in which the bonding wires 4a to 4c are all covered with the insulating layers 9a to 9c, only a part of the bonding wires 4a to 4c may be covered with the insulating layer. For example, the bonding wire 4b, when located adjacent to a member having a different potential such as the external connection terminal 6a, may only be covered with the insulating layer 9b. Selectively covering a part of the bonding wires 4a to 4c with the insulating layer can reduce the material cost and the process cost.

The insulating layers 9a to 9c have greater hardness than the sealing material 7, and also have a higher Young's modulus than the sealing material 7. The Young's modulus of the insulating layers 9a to 9c is in a range of about 100 kPa or higher and 10 GPa or lower, and preferably in a range of about 100 kPa or higher and 1 GPa or lower. Setting the Young's modulus of the insulating layers 9a to 9c to 100 kPa or higher can effectively avoid a cause of bubbles inside the insulating layers 9a to 9c. In addition, setting the Young's modulus of the insulating layers 9a to 9c to 1 GPa or lower can effectively keep the flexibility of the insulating layers 9a to 9c with respect to the bonding wires 4a to 4c.

A ratio of the Young's modulus of the insulating layers 9a to 9c to the Young's modulus of the sealing material 7 is about 10 or greater, for example. Setting the ratio to 10 or greater can effectively avoid a cause of bubbles inside the insulating layers 9a to 9c.

The insulating layers 9a to 9c have relative permittivity which may be either higher or lower than that of the sealing material 7. Setting the relative permittivity of the insulating layers 9a to 9c to be a lower value can relax the electric field intensity if bubbles are caused inside the sealing material 7 and an air layer having permittivity which is one is led to be inserted. The relative permittivity of the insulating layers 9a to 9c is about seven or lower, and preferably about three or lower, for example. Setting the relative permittivity of the insulating layers 9a to 9c to seven or lower can relax the electric field intensity if bubbles are caused inside the sealing material 7. Setting the relative permittivity of the insulating layers 9a to 9c to three or lower can further decrease the electric field intensity if bubbles are caused inside the sealing material 7. Decreasing the relative permittivity of the insulating layers 9a to 9c is a technical idea opposite to that used for graded insulation that stacks insulating layers having higher permittivity as closer to a middle material so as to equalize the electric field intensities applied to the respective layers.

As a ratio of the permittivity of the insulating layers 9a to 9c to the permittivity of the sealing material 7 is smaller, the electric field intensity toward the surfaces of the insulating layers 9a to 9c (toward the sealing material 7) can be further relaxed. The ratio of the permittivity of the insulating layers 9a to 9c to the permittivity of the sealing material 7 is about three or lower, for example. Setting ratio of the permittivity of the insulating layers 9a to 9c to the permittivity of the sealing material 7 to three or lower can effectively relax the electric field intensity toward the surfaces of the insulating layers 9a to 9c. The ratio of the permittivity of the insulating layers 9a to 9c to the permittivity of the sealing material 7 may be set to about two or lower, may be set to about one or lower, or may be set to about 0.5 or lower.

The thickness of the insulating layers 9a to 9c can be controlled such that a viscosity of the insulating layers 9a to 9c before curing, a drawing-up speed upon the use of the dipping application, the number of the applying steps upon the use of the spraying or dipping application, and the like are adjusted. The thickness of the respective insulating layers 9a to 9c may be substantially constant, or may vary so as to have thicker and thinner parts. The greater thickness of the insulating layers 9a to 9c can further relax the electric field intensity toward the surfaces of the insulating layers 9a to 9c (toward the sealing material 7). The thickness of the respective insulating layers 9a to 9c is set in a range of about 25 micrometers or greater and 500 micrometers or less, for example. Setting the thickness of the insulating layers 9a to 9c to 25 micrometers or greater can effectively relax the electric field intensity of the insulating layers 9a to 9c on the surface side.

A heat-releasing base 8 is provided on the other main surface side (on the bottom surface side) of the insulated circuit substrate 1 with a bonding layer 14 interposed. The bonding layer 14 includes sintering material or solder, for example. The bonding layer 14 may include the same material as the bonding layer 2, or may include material different from that included in the bonding layer 2. The heat-releasing base 8 includes metal such as copper (Cu).

A heat-releasing fin 13 is provided on the bottom surface side of the heat-releasing base 8 with a bonding layer 15 interposed. Alternatively, the heat-releasing fin 13 may be provided on the bottom surface side of the insulated circuit substrate 1 with the bonding layer 15 interposed without the provision of the heat-releasing base 8. Alternatively, the bottom surface of the heat-releasing base 8 may be exposed when the heat-releasing fin 13 is not provided.

The heat-releasing fin 13 includes metal such as copper (Cu). The bonding layer 15 includes sintering material, solder, or thermal interface material (TIM), for example. The TIM as used herein can be thermal-conductive material (a thermal compound), such as thermal-conductive grease, an elastomer sheet, room temperature vulcanization (RTV) rubber, gel, phase-change material, and silver wax. The bonding layer 15 may include either the same material as or material different from that included in the respective bonding layers 2 and 14.

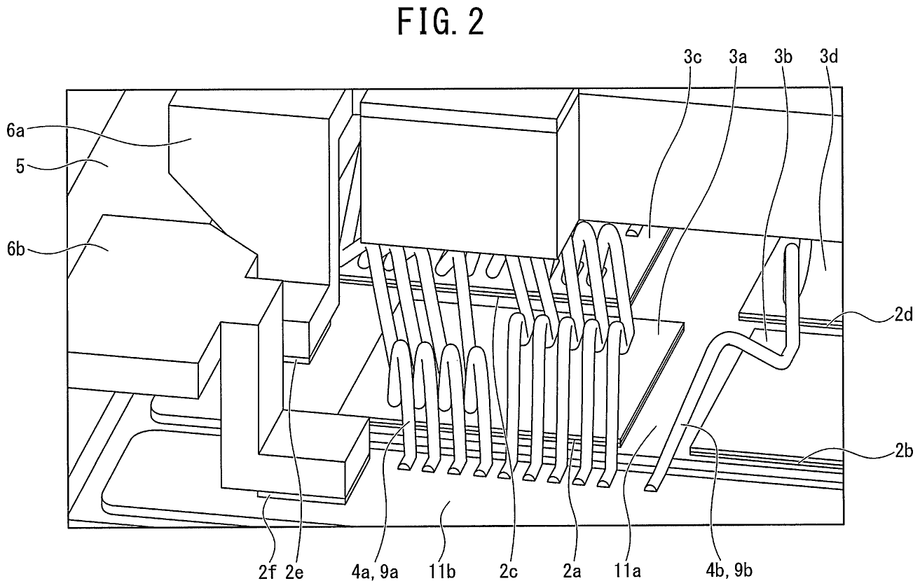

FIG. 2 is a perspective view illustrating another example of the semiconductor device according to the present embodiment. A plurality of semiconductor chips 3a to 3d are provided on the top surface side of the conductive layer 11a with the bonding layers 2a to 2d interposed. The external connection terminal 6a is provided on the top surface side of the conductive layer 11a with a bonding layer 2e interposed. The external connection terminal 6b is provided on the top surface side of the conductive layer 11b with a bonding layer 2f interposed. The case 5 is provided to surround the circumferences of the conductive layers 11a and 11b, the bonding layers 2a to 2f, and the semiconductor chips 3a to 3d. FIG. 2 omits the illustration of the sealing material 7 filled inside the case 5 to seal the conductive layers 11a and 11b, the bonding layers 2a to 2f, and the semiconductor chips 3a to 3d.

The plural bonding wires 4a each covered with the insulating layer 9a electrically connect the first main electrode on the top surface side of the semiconductor chip 3a, the first main electrode on the top surface side of the semiconductor chip 3c, and the conductive layer 11b together. The bonding wire 4b covered with the insulating layer 9b electrically connects the first main electrode on the top surface side of the semiconductor chip 3b, the first main electrode on the top surface side of the semiconductor chip 3d, and the conductive layer 11b together.

The potential of the bonding wires 4a and 4b illustrated in FIG. 2 is common to that of the external connection terminal 6b electrically connected to the first main electrodes on the top surface side of the semiconductor chips 3a to 3d, and is different from that of the external connection terminal 6a electrically connected to the second main electrodes on the bottom surface side of the semiconductor chips 3a to 3d. The distance from the respective bonding wires 4a and 4b to the external connection terminal 6a having the potential different from that of the external connection terminal 6a may be about five millimeters or smaller with the sealing material 7 interposed. For example, only one of the bonding wires 4a located closest to the external connection terminal 6a may be covered with the insulating layer 9a and distant from the external connection terminal 6a by about five millimeters or smaller, while the other bonding wires 4a and 4b may be distant from the external connection terminal 6a by more than five millimeters without being covered with the insulating layers.

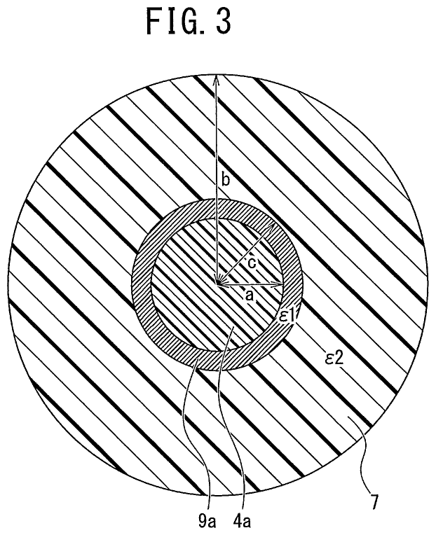

FIG. 3 illustrates the bonding wire 4a, the insulating layer 9a, and the sealing material 7 in cross section in the longitudinal direction of the bonding wire 4a in a case of modeling the sealing material 7 into a cylinder concentric with the bonding wire 4a. The outer circumferential surface of the sealing material 7 corresponds to the surface of the terminal having a different potential. The electric field concentration is maximum around the circumference of the bonding wire 4a.

In FIG. 3, “ε1” denotes the relative permittivity of the insulating layer 9a, “ε2” denotes the relative permittivity of the sealing material 7, “a” demotes a radius of the bonding wire 4a, “b” denotes a distance between the center of the bonding wire 4a and the terminal surface, and “c” denotes an outer circumferential radius of the insulating layer 9a.

The electric field intensity E(r) of the bonding wire when not covered with the insulating layer is given by:

$$\begin{matrix}[ Math . 1 ] & \\ E ( r ) = v / r ( ln \cdot b ’ / a ’ ) & ( 1 )\end{matrix}$$

where “a′” is the radius of the bonding wire not covered and “b′” is the distance between the center of the bonding wire not covered and the terminal surface.

With regard to the bonding wire 4a covered with the insulating layer 9a as illustrated in FIG. 3, the electric field intensity E1(r) inside the insulating layer 9a and the electric field intensity E2(r) outside the insulating layer 9a are each given by:

$$\begin{matrix}[ Math . 2 ] & \\ E 1 ( r ) = V / ε1 r ( 1 / ε1 \cdot ln \cdot c / a + 1 / ε2 \cdot ln \cdot b / c ) & ( 2 )\end{matrix}$$

$$\begin{matrix}[ Math . 3 ] & \\ E 2 ( r ) = V / ε2 r ( 1 / ε1 \cdot ln \cdot c / a + 1 / ε2 \cdot ln \cdot b / c ) & ( 3 )\end{matrix}$$

The semiconductor device according to the present embodiment is configured such that the covering thickness (c−a) of the insulating layer 9a is set so as to meet E2 (a, b, c, r=c)≤E (a′, b′, r=a′). Further, the present embodiment is particularly effective when the distance between the elements having different potentials, (b−a) and (b′−a′), is in a region of about five millimeters or smaller.

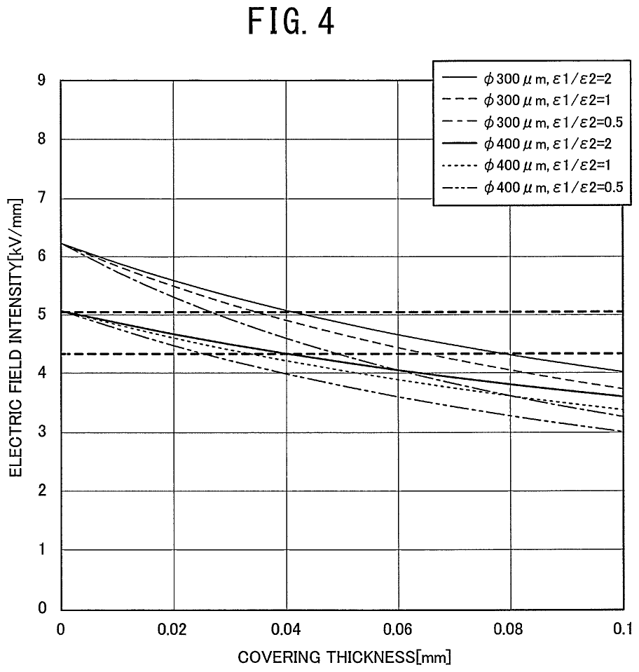

FIG. 4 is a graph, as an example of the semiconductor device according to the present embodiment, showing a relation between the thickness of the insulating layer and the electric field intensity of the insulating layer on the front surface side (toward the sealing material) when the voltage of 3.3 kV is applied between the bonding wire covered with the insulating layer and the terminal having a different potential while the distance between the bonding wire and the terminal is set to five millimeters. This example is illustrated with two cases regarding the diameter of the bonding wire, which are 300 micrometers and 400 micrometers, and with three cases regarding the ratio (ε1/ε2) of the relative permittivity ε1 of the insulating layer to the relative permittivity ε2 of the sealing material, which are 0.5, 1, and 2.

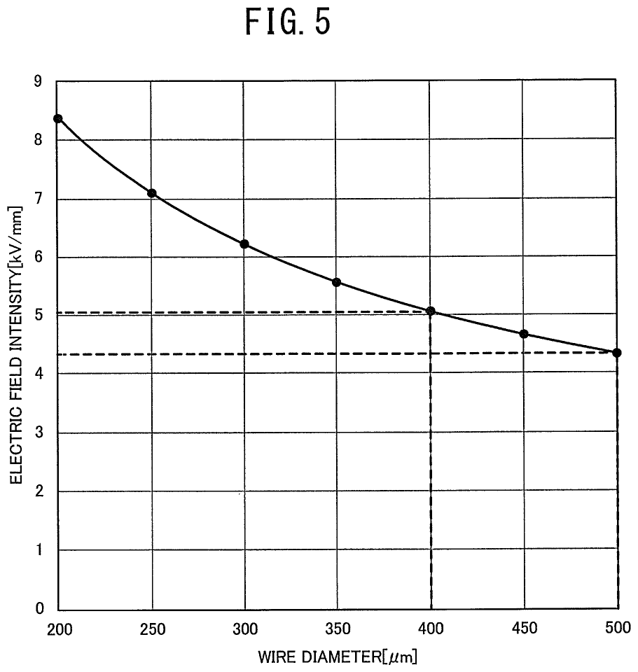

FIG. 5 is a graph, as a comparative example of the semiconductor device according to the present embodiment, showing a relation between the diameter of the bonding wire with no covering and the electric field intensity of the bonding wire on the front surface side when the voltage of 3.3 kV is applied between the bonding wire and the terminal having a different potential while the distance between the bonding wire and the terminal is set to five millimeters. FIG. 4 and FIG. 5 each indicate, for convenience of explanation, the additional broken lines at the positions of the electric field intensities corresponding to the diameters of 400 micrometers and 500 micrometers of the bonding wire with no covering in FIG. 5.

As shown in FIG. 4, the electric field intensity can be relaxed as the thickness of the insulating layer is increased in both cases in which the bonding wire covered with the insulating layer has the diameter of 300 micrometers and has the diameter of 400 micrometers. The electric field intensity can also be relaxed as the ratio (ε1/ε2) of the relative permittivity ε1 of the insulating layer to the relative permittivity ε2 of the sealing material is smaller in both cases in which the bonding wire covered with the insulating layer has the diameter of 300 micrometers and has the diameter of 400 micrometers.

As illustrated in FIG. 4 and FIG. 5, the electric field intensity can be relaxed, as in the case of the bonding wire with no covering having the diameter of 400 micrometers, when the bonding wire is covered with the insulating layer with the thickness of 25 micrometers or greater in the case in which the ratio (ε1/ε2) of the relative permittivity ε1 of the insulating layer to the relative permittivity ε2 of the sealing material is 0.5 and the diameter of the bonding wire is 300 micrometers.

Further, as illustrated in FIG. 4 and FIG. 5, the electric field intensity can be relaxed, as in the case of the bonding wire with no covering having the diameter of 500 micrometers, when the bonding wire is covered with the insulating layer with the thickness of 50 micrometers or greater in the case in which the ratio (ε1/ε2) of the relative permittivity ε1 of the insulating layer to the relative permittivity ε2 of the sealing material is 0.5 and the diameter is 300 micrometers.

Further, as illustrated in FIG. 4 and FIG. 5, the electric field intensity can be relaxed, as in the case of the bonding wire with no covering with the diameter of 500 micrometers, when the bonding wire is covered with the insulating layer with the thickness of 25 micrometers or greater in the case in which the ratio (ε1/ε2) of the relative permittivity ε1 of the insulating layer to the relative permittivity ε2 of the sealing material is 0.5 and the diameter is 400 micrometers.

The semiconductor device according to the present embodiment has the configuration in which the outer circumferences of the bonding wires 4a to 4c, on which the electric field tends to be concentrated, are covered with the insulating layers 9a to 9c including harder material than that included in the sealing material 7 such as silicone gel, as illustrated in FIG. 1 and FIG. 2. The use of the harder material can avoid a cause of bubbles inside the insulating layers 9a to 9c, suppressing bubbles between the bonding wires 4a to 4c and the sealing material 7 accordingly. The interposition of the insulating layers 9a to 9c between the bonding wires 4a to 4c and the sealing material 7 can improve the insulating reliability if separation or bubbles in the sealing material 7 cannot be completely avoided.

Conventionally, bubbles caused in the sealing material located adjacent to the bonding wires or around the interface between the sealing material and other materials stick to the bonding wires if not covered with any insulating member, and voids similar to separation tend to be provided around the bonding wires. In contrast, the semiconductor device according to the present embodiment including the insulating layers 9a to 9c covering the outer circumferences of the bonding wires 4a to 4c can prevent bubbles, if caused at the interface between the sealing material and the other materials, from reaching the bonding wires. This can suppress bubbles caused around the bonding wires, so as to avoid a provision of any voids accordingly.

The semiconductor device according to the present embodiment thus can exhibit the electric-field relaxation effect, equivalent to the case of including the wires having a greater thickness, with not necessity of a change in the wire diameter regardless of whether the maximum rated voltage of the semiconductor chip 3 is as high as about 3.3 kV or higher, so as to allow a design with a reduction in size equivalent to the case in which the maximum rated voltage of the semiconductor chip 3 is about 1.7 kV. The semiconductor device according to the present embodiment thus can use the bonding wires 4a to 4c having a relatively small diameter of about 300 micrometers even when the maximum rated voltage of the semiconductor chip 3 is about 3.3 kV, so as to decrease the size of the gate pad used only for signal input on the element surface. Further, the total costs can be reduced, particularly when a SiC element more expensive than a Si element is used, since the configuration according to the present embodiment can decrease the size of the element.

Further, the semiconductor device according to the present embodiment uses the insulating layers 9a to 9c covering only the outer circumferences of the bonding wires 4a to 4c, so as to keep the flexibility with respect to the bonding wires 4a to 4c regardless of whether the insulating layers 9a to 9c are harder than the sealing material 7, avoiding a separation between the bonding wires 4a to 4c and the insulating layers 9a to 9c accordingly.

### OTHER EMBODIMENTS

As described above, the invention has been described according to the present embodiment, but it should not be understood that the description and drawings implementing a portion of this disclosure limit the invention. Various alternative embodiments of the present disclosure, examples, and operational techniques will be apparent to those skilled in the art from this disclosure.

For example, while the present embodiment illustrates the case in which the bonding wires 4a to 4c included in the semiconductor device are connected to the first main electrode 31 of the semiconductor chip 3, the conductive layers 11a and 11b, and the external connection terminals 6a and 6b, the targets to which the bonding wires 4a to 4c are connected are not necessarily limited to this case, and can be determined as appropriate. Further, the number of the bonding wires 4a to 4c included in the semiconductor device according to the present embodiment can also be changed as appropriate.

In addition, the respective configurations disclosed in the present embodiment can be combined together as appropriate without contradiction with each other. As described above, the invention includes various embodiments of the present disclosure and the like not described herein. Therefore, the scope of the present disclosure is defined only by the technical features specifying the present disclosure, which are prescribed by claims, the words and terms in the claims shall be reasonably construed from the subject matters recited in the present specification.

1. A semiconductor device comprising:
a semiconductor chip having a first main electrode on a top surface side and a second main electrode on a bottom surface side;
a bonding wire connected to the first main electrode;
an insulating layer covering an outer circumference of the bonding wire; and
a sealing material sealing the semiconductor chip, the bonding wire, and the insulating layer,
wherein a ratio of a Young's modulus of the insulating layer to a Young's modulus of the sealing material is 10 or greater, and
a ratio of permittivity of the insulating layer to permittivity of the sealing material is three or smaller.

2. The semiconductor device of claim 1, wherein the Young's modulus of the insulating layer is 100 kPa or greater and 10 GPa or smaller.

3. The semiconductor device of claim 1, wherein the insulating layer has relative permittivity of seven or smaller.

4. The semiconductor device of claim 1, wherein the bonding wire has a diameter of 300 micrometers or greater.

5. The semiconductor device of claim 1, wherein the insulating layer has a thickness of 25 micrometers or greater.

6. The semiconductor device of claim 1, wherein the insulating layer has a thickness of 500 micrometers or less.

7. The semiconductor device of claim 1, wherein the semiconductor chip has a maximum rated voltage of 1.7 kV or higher.

8. The semiconductor device of claim 1, wherein the bonding wire is located at a position separated by five millimeters or smaller from a terminal having a potential different from a potential of the bonding wire with the sealing material interposed.

9. The semiconductor device of claim 8, wherein the second main electrode is electrically connected to the terminal.

10. The semiconductor device of claim 1, wherein the insulating layer includes at least one kind of resin selected from the group consisting of polyamide resin, polyimide resin, polyamide imide resin, polyester resin, epoxy resin, phenol resin, fluorine resin, acrylic resin, silicone resin, polyolefin resin, and polyether imide resin.

11. The semiconductor device of claim 1, wherein the sealing material includes silicone gel or fluorine gel.
